(19) United States
(12) Patent Application Publication
(10) Pub. No.: US 2012/0146162 A1
(43) Pub. Date: Jun. 14, 2012

(54) NANOSENSOR AND METHOD OF MANUFACTURING THE SAME

(75) Inventors: Seong-ho CHO, Gwacheon-si (KR); Dong-ho LEE, Seongnam-si (KR); Jeo-young SHIM, Yongin-si (KR)

(73) Assignee: Samsung Electronics Co., Ltd., Gyeonggi-do (KR)

(21) Appl. No.: 13/323,417

(22) Filed: Dec. 12, 2011

(30) Foreign Application Priority Data
Dec. 13, 2010 (KR) 10-2010-0127092
Nov. 8, 2011 (KR) 10-2011-0115928

(51) Int. Cl. H01L 29/66; H01L 21/02; B82Y 15/00; B82Y 40/00

(52) U.S. Cl. 257/414; 438/49; 257/E29.166; 977/953; 977/840; 257/E21.002

(57) ABSTRACT

A nanosensor comprising a substrate in which an opening defining a hole is formed; a first layer disposed on the substrate, which comprises a first nanopore in communication with the hole in the substrate; and a second layer contacted or coupled with the first layer and formed of a porous material.

### CROSS-REFERENCE TO RELATED APPLICATIONS

This application claims the benefit of Korean Patent Application No. 10-2010-0127092, filed on Dec. 13, 2010 and No. 10-2011-0115928, filed on Nov. 8, 2011, in the Korean Intellectual Property Office, the disclosures of which are incorporated herein in their entirety by reference.

### BACKGROUND OF THE INVENTION

The Maxam-Gilbert and Sanger methods are techniques commonly used to determine the order of bases of deoxyribonucleic acid (DNA). The Maxam-Gilbert method involves randomly performing cleavage at specific bases and separating DNA strands having different lengths by using electrophoresis. The Sanger method involves synthesizing a complementary DNA by putting a template DNA, a DNA polymerase, a primer, a normal deoxynucleotide triphosphate (dNTP), and a dideoxynucleotide triphosphate (ddNTP) into a tube. When the ddNTP is added while the complementary DNA is synthesized, DNA synthesis is terminated. The order of bases of the DNA may be determined by obtaining complementary DNAs having different lengths, and separating the complementary DNAs by using electrophoresis. However, such methods used to determine the order of bases of DNA are time- and effort-consuming. Accordingly, new DNA sequencing methods are needed.

### SUMMARY OF THE INVENTION

Provided herein is a nanosensor comprising (a) a substrate comprising an opening defining a hole; (b) a first layer on the substrate, wherein the first layer comprises a first nanopore coupled with, connected to, or otherwise in communication with the opening defining the hole in the substrate; and (c) a second layer in contact with or coupled to the first layer, wherein the second layer is a porous material.

Also provided herein is a method of manufacturing a nanosensor, the method comprising (a) forming an opening defining a hole in a substrate; (b) forming a first layer on the substrate; (c) forming a nanopore in the first layer, wherein the nanopore is coupled with, connected to, or otherwise in communication with the hole defining an opening in the substrate; and (d) forming a second layer of a porous material in contact with or coupled to the first layer.

These and/or other aspects of the invention will become apparent and more readily appreciated from the following detailed description of the invention and its various embodiments, taken in conjunction with the accompanying drawings.

### BRIEF DESCRIPTION OF THE DRAWINGS

FIG. 1A is a plan view of a nanosensor according to an embodiment of the present invention;

FIG. 1B is a cross-sectional view taken along line A-A′ of the nanosensor of FIG. 1A;

FIG. 1C is a cross-sectional view of a nanosensor that comprises a substrate surrounded by a housing, according to an embodiment of the present invention;

FIG. 2A is a plan view of a nanosensor according to an embodiment of the present invention;

FIG. 2B is a cross-sectional view taken along line B-B′ of the nanosensor of FIG. 2A;

FIG. 3A is a plan view of a nanosensor according to an embodiment of the present invention;

FIG. 3B is a cross-sectional view taken along line C-C′ of the nanosensor of FIG. 3A;

FIGS. 4A and 4B are cross-sectional views for describing a method of manufacturing a nanosensor, according to an embodiment of the present invention;

FIGS. 5A through 5C are cross-sectional views of nanosensors according to embodiments of the present invention;

FIG. 6 is a schematic diagram of light incident on a first nanopore and light emitted from the first nanopore, according to an embodiment of the present invention;

FIGS. 7A and 7B are graphs of an intensity of light according to a depth of a nanopore, according to an embodiment of the present invention;

FIGS. 8A through 8C are cross-sectional views of nanosensors according to other embodiments of the present invention; and

FIGS. 9A through 9F are cross-sectional views of a nanosensor in various stages of manufacturing, according to an embodiment of the present invention.

### DETAILED DESCRIPTION

The invention provides a nanosensor comprising (a) a substrate comprising an opening defining a hole; (b) a first layer on the substrate, wherein the first layer comprises a first nanopore coupled with, connected to, or otherwise in communication with the opening defining the hole in the substrate; and (c) a second layer in contact with or coupled to the first layer, wherein the second layer is a porous material.

The substrate can comprise, consist essentially of, or consist of any suitable material, for instance, a semiconductor material (e.g., silicon (Si), germanium (Ge), GaAs, GaN, or the like), a polymer material (e.g., inorganic or organic polymer), or other suitable materials such as quartz, glass, or the like.

The substrate comprises an opening defining a hole of a suitable size. The substrate comprises a top surface (top face) and bottom surface (bottom face) arranged substantially parallel to one another and defining a thickness therebetween. The hole forms a passage through the thickness of the substrate from a bottom face of the substrate to a top face of the substrate, the top face being the surface upon which the first layer is formed (coupled or connected). The hole, thus, may be referred to as a passageway or tunnel through the thickness of the substrate connecting an opening in a top surface of the substrate with an opening in a bottom surface of the substrate. The openings defining the hole can be of any suitable shape, but are typically approximately circular. Generally, the hole (e.g., openings defining a hole) will have a diameter of several microns or less. The hole can, optionally, taper from the bottom surface of the substrate to the top surface of the substrate. In other words, the hole can have a diameter at the bottom surface of the substrate that is larger than the diameter of the hole at the top surface of the substrate.

The substrate is referred to herein as having a “top” and “bottom” surface, and references are made to positions “below” and “above” the substrate. Such referenes are merely for the purposes of explaining and illustrating the invention and various embodiments thereof. These references are not intended to imply any particular orientation of the device in use, and are not intended to limit the invention in any other manner.

The first layer can comprise, consist essentially of, or consist of an insulating material, and generally is a thin film with a thickness of several nanometers or more. Suitable insulating material can comprise, for example, SiN, SiO₂, Al₂O₃, TiO₂, BaTiO₃, PbTiO₃, or the like, as well as mixtures of the foregoing. The insulating materials also can comprising doping agents. For example, the first layer can comprise SiN doped with metal, SiₓN_{y}(x>>y), with a very high composition ratio of Si to N, or the like. In addition, or instead, the first layer can comprise at least one metal material, desirably a metal that absorbs light such as gold (Au), silver (Ag), aluminum (Al), copper (Cu), TiN, or the like, including mixtures thereof. Any combination of the foregoing materials also can be used. In one aspect of the invention, the first layer material is selected to be a material that does not transmit light therethrough (i.e., is partly or completely opaque to light) or absorbs or reflects light. In particular, it is desirable in some embodiments that the first layer is more opaque to light than the porous material of the second layer. In this regard, the light referred to is the light used to cure the porous material of the second layer, as described in detail with respect to the method of manufacturing the nanosensor.

The first layer comprises a first nanopore, wherein a nanonpore is an opening defining a hole in the layer. The nanopore can be any suitable shape, but is generally approximately circular. The nanopore is in communication (e.g., in fluid communication) with the opening defining a hold in the substrate, such that a molecule passing through the hole in the substrate will reach the nanopore. Thus, the first nanopore can be coupled or connected (e.g., fluidly coupled or connected) to the hole in the substrate, or otherwise arranged in communication therewith, for instance, by being positioned in a region of the first layer that overlays or aligns with the hole in the substrate. The first nanopore can have any suitable diameter ranging from several nanometers to several tens of nanometers (e.g., 1-50 nm). The size of the nanopore will be selected based, in part, on the target molecule to be analyzed.

The nanosensor may further comprise an electrode layer disposed on the first layer (e.g., between the first layer and the second layer). The electrode layer can comprise a second nanopore in communication (e.g., in fluid communication) with the first nanopore, such that a molecule passing through the first nanopore in the first layer will reach the second nanopore. Thus, the second nanopore can be coupled or connected (e.g., fluidly coupled or connected) to the first nanopore, or otherwise arranged in communication therewith, i.e., positioned in a region of the electrode layer that overlays or is aligned with the first nanopore. Alternatively, the electrode layer may include a first electrode and a second electrode that are spaced apart from each other by a distance that defines a nanogap, wherein the nanogap is coupled with, connected to, or otherwise in communication with the first nanopore. In other words, the nanogap is positioned in a region of the electrode layer, between the first and second electrodes, that overlays or is aligned with the first nanopore, such that a molecule passing though the first nanopore will reach the nanogap. The second nanopore or the nanogap can have a diameter approximately equal to or greater than the diameter of the first nanopore. The electrode layer and/or first and second electrodes can comprise, consist essentially of, or consist of any suitable conductive material, such as Cu, Al, Au, Ag, and the like. In addition, or instead, the electrodes can comprise one or more graphene sheets.

The electrode layer, or first and/or second electrodes, can each further comprise an electrode contact. If necessary depending upon the configuration of the porous layer relative to the electrode layer, the one or more electrode contacts can extend through a portion of the porous layer, so as to be exposed through the porous layer and accessible for connection to a voltage source, etc. The electrode contacts can comprise any of the conductive materials described above with respect to the electrodes, can be made of the same material or a different material than the electrode to which they are attached.

The nanosensor comprises a second layer of a porous material coupled to, connected with, or in contact with the first layer. The second layer can be positioned relative to the first layer such that the porous material covers or occupies the first nanopore. Thus, for example, the second layer may be disposed on the first layer or portion thereof sufficient to cover the nanopore, disposed on an electrode layer or portion thereof sufficient to cover the nanopore, and/or the second layer can be filled in at least a portion of the first nanopore and, optionally, the second nanopore or nanogap in the electrode layer if present. The second layer of porous material should have a thickness sufficient to reduce the translocation speed of a target molecule (e.g., DNA) passing through the nanosensor (e.g., nanopore of the nanosensor) as compared to the translocation speed in the absence of the porous material, but not so thick as to prevent translocation of the target molecule.

The porous material can comprise, consist essentially of, or consist of any suitable material through which a nucleic acid molecule (e.g., single stranded or double stranded DNA) can pass, but which will reduce the translocation speed of the molecule passing through the nanopore as compared to the translocation speed of the molecule through the nanopore in the absence of the porous material. Non-limiting examples of useful porous materials include gelatin, poly(ethylene glycol) dimethacrylate (PEGDMA), combinations thereof, and the like. The thickness and porosity of the second layer can be selected according to the desired degree of reduction of the translocation speed of target molecules to be detected. For example, the thickness of the second layer 30 may range from several nm to several μm.

The nanosensor may further comprise a housing surrounding the substrate and any layers thereupon. The substrate can be positioned in the housing, for example, in a manner such that the substrate divides the housing into two regions (a first and second regions) with respect to the substrate. The first and second regions can be in communication with one another (in fluid communication or fluidly coupled) through the opening defining the hole in the substrate, the first nanopore, and the optional second nanopore or nanogap. According to a further aspect, each of the two regions in the housing can comprise a third electrode and a fourth electrode, respectively, regardless of whether a first or second electrode (or any electrode layer) is present. The housing can further contain water or an electrolyte solution.

Reference will now be made in detail to various embodiments, examples of which are illustrated in the accompanying drawings, wherein like reference numerals refer to like elements throughout. The invention should not be construed as limited in any way to the descriptions or drawings of specific embodiments set forth herein. Rather, the embodiments are merely described below, and by reference to the figures, to further explain and illustrate aspects of the invention. Sizes of elements in the drawings may be exaggerated for clarity and convenience.

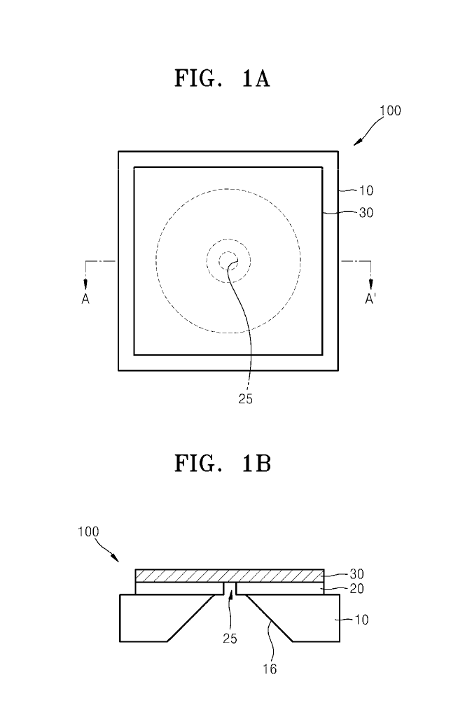

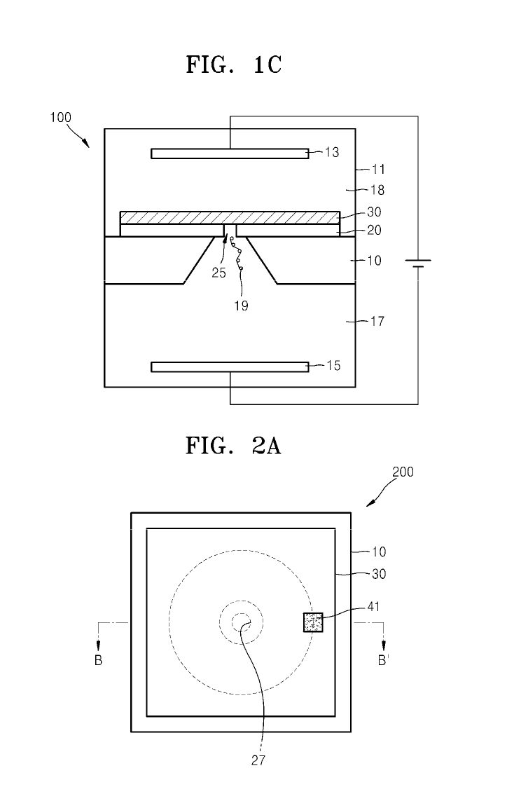

FIG. 1A is a plan view of a nanosensor 100 according to an embodiment of the present invention. FIG. 1B is a cross-sectional view taken along line A-A′ of the nanosensor 100 of FIG. 1A. FIG. 1C is a cross-sectional view of the nanosensor 100 surrounded by a housing 11, according to an embodiment of the present invention.

Referring to FIGS. 1A and 1B, the nanosensor 100 comprises a substrate 10 in which an opening defining a hole 16 is formed, a first layer 20 disposed on the substrate 10 and including a first nanopore 25 connected to the hole 16, and a second layer 30 disposed on the first layer 20 and formed of a porous material.

The substrate 10 may support the first layer 20 and the second layer 30, which are disposed thereon, and may be formed of a semiconductor material, a polymer material, or the like. The semiconductor material may comprise, for example, silicon (Si), germanium (Ge), GaAs, GaN, or the like. The polymer material may include, for example, an organic polymer or an inorganic polymer. The substrate 10 also may be formed of quartz, glass, or the like.

The opening defining a hole 16 in the substrate 10 may have a size (diameter) of several microns or less, as described herein, and may taper from a bottom surface of the substrate 10 toward a top surface of the substrate 10 on which the first layer 20 is disposed. That is, the hole or passageway 16 may have a tapered shape that narrows from a lower portion toward an upper portion of the substrate 10. Thus, the hole 16 having a tapered shape may guide target molecules to be easily introduced from the lower portion of the substrate 10 to the first nanopore 25.

The first layer 20 may be disposed on a predetermined portion of the substrate 10 so as to cover the opening defining the hole 16 in the substrate. The first layer 20 may be formed of an insulating material. The insulating material can comprise, for example, SiN, SiO₂, Al₂O₃, TiO₂, BaTiO₃, PbTiO₃, or the like. Desirably, the first layer 20 does not transmit light therethrough or may reflect or absorb light. For example, the first layer 20 can comprise SiN doped with metal, SiₓN_{y}(x>>y) with a very high composition ratio of Si to N, or the like. In addition, or instead, the first layer 20 can comprise at least one metal material that absorbs and/or reflects light, such as gold (Au), silver (Ag), aluminum (Al), copper (Cu), or TiN. The first layer can be a thin film with a thickness of several nm or more.

The first nanopore 25 in the first layer 20 may be in communication with, coupled to, or connected to the hole 16 of the substrate 10. That is, the first nanopore 25 may be formed (positioned) in a portion of the first layer 20, which corresponds to the hole 16. The size of the first nanopore 25 may be selected according to sizes of target molecules to be detected. The diameter of the first nanopore 25 may range from one or several nm to several tens of nm. For example, the diameter of the first nanopore 25 may range from about 1 nm to about 50 nm, or as otherwise described herein.

The second layer 30 may be disposed on the first layer 20 and/or in the first nanopore, and may be formed of a porous material. The porous material can comprise, for example, gelatin, poly(ethylene glycol) dimethacrylate (PEGDMA), or the like. The thickness and porosity of the second layer 30 may be selected according to the desired degree of reduction of the translocation speed of target molecules to be detected. For example, the thickness of the second layer 30 may range from several nm to several μm. The second layer 30 may be formed (positioned) on a predetermined portion of the first layer 20 so as to cover and/or fill the first nanopore 25 in the first layer 20. Referring to FIG. 4B, a second layer 35 may be disposed on the first nanopore 25 and a portion of the first layer 20 surrounding the first nanopore 25 so as to cover or occupy the first nanopore 25. The second layer 30 may lower a translocation speed of target molecules transmitted through the first nanopore 25. Typically, when deoxyribonucleic acid (DNA) is sequenced by using a nanopore, since a translocation speed of DNA passing through the nanopore is too high, that is, about 10⁷ base/sec, it is impossible to identify four different bases with an interval of about 0.37 nm, for example, adenine, guanine, cytosine, and thymine. Thus, translocation of an entire DNA strand may be determined by measuring the time taken for translocation of an entire DNA strand. However, according to the present embodiment, the second layer 30 may lower the translocation speed of target molecules passing through the first nanopore 25, and thus, the nanosensor 100 may identify bases included in a DNA strand. Thus, the nanosensor 100 may rapidly and accurately determine a base sequence of a DNA strand by using a next generation sequencing method.

Referring to FIG. 1C, the nanosensor 100 may further include a housing 11 surrounding the substrate 100 and any layers disposed thereupon. The housing 11 may be divided into two regions (a first and second region) with respect to the substrate 10. That is, the housing 11 may include a first region 17 disposed below the substrate 10 and a second region 18 disposed above the substrate 10. The first region 17 and the second region 18 may be in communication with, coupled, or connected (e.g., fluidly coupled or fluidly connected) through the first nanopore 25. In addition, the first region 17 and the second region 18 of the housing may include first and second electrodes 15 and 13, respectively. A voltage may be applied to the first and second electrodes 15 and 13 from an external power source. The first electrode 15 included in the first region 17 may be a negative (−) electrode and the second electrode 13 included in the second region 18 may be a positive (+) electrode. The housing 11 may be filled (partially or entirely) with a buffer solution such as water, deionized water, an electrolyte solution, or the like. The buffer solution may be a translocation medium of target molecules to be detected by the nanosensor 100.

Target molecules may be introduced from outside the nanosensor 100 to the first region 17 below the substrate 10. The target materials may include, for example, nucleotide, nucleoside, single-strand DNA, double-strand DNA, and the like. FIG. 1C shows single-strand DNA 19 as an example of target molecules. Since the single-strand DNA 19 is negatively charged, the single-strand DNA 19 may be translocated from the first region 17 including the first electrode 15, i.e., a negative (−) electrode, to the second region 18 including the second electrode 13, i.e., a positive (+) electrode, by an electric field generated by the voltage applied to the first and second electrodes 15 and 13. That is, the single-strand DNA 19 introduced to the first region 17 is translocated to a region adjacent to the hole 16 in the substrate 10 by the electric field and is guided by the hole 16 towards the first nanopore 25. When the single-strand DNA 19 passes through the first nanopore 25, the single-strand DNA 19 may reach the second layer 30 that is porous so that a translocation speed of the single-strand DNA 19 is lowered. Thus, when the single-strand DNA 19 passes through the first nanopore 25, a base constituting the single-strand DNA 19 may be identified by measuring an electric signal change at two ends of the first nanopore 25, for example, a change in ion currents that flow through the first nanopore 25. That is, the base constituting the single-strand DNA 19 may be identified by measuring a current change at a point of time when the single-strand DNA 19 is clogging (i.e., occupying) the first nanopore 25 while passing through the first nanopore 25. The change in current can be measured by way of electrodes 13 and 15, or by other techniques.

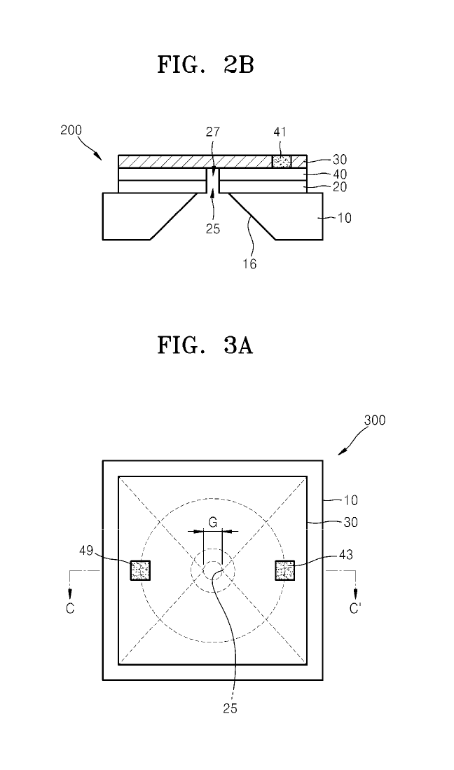

FIG. 2A is a plan view of a nanosensor 200 according to another embodiment of the present invention. FIG. 2B is a cross-sectional view taken along line B-B′ of the nanosensor 200 of FIG. 2A. The nanosensor 200 will be described in terms of its differences from the nanosensor 100 of FIGS. 1A through 1C.

Referring to FIGS. 2A and 2B, the nanosensor 200 comprises a substrate 10 in which an opening defining a hole 16 is formed, a first layer 20 disposed on the substrate 10 and including a first nanopore 25 connected to or otherwise in communication with the hole 16, an electrode layer 40 disposed on the first layer 20 and including a second nanopore 27 correspondingly connected to or otherwise in communication with the first nanopore 25, and the second layer 30 formed of a porous material disposed on the electrode layer 40 so as to cover the first and second nanopores (i.e., the passageway defined by the first and second nanopores and the hole in the substrate).

The electrode layer 40 may be formed of a conductive material. The conductive material can comprise, for example, Cu, Al, Au, Ag, and the like. The second nanopore 27 may be formed in the electrode layer 40 and may be formed by using, for example, a TEM, a SEM, or the like. In addition, the second nanopore 27 may be formed by using an electron beam, a focused ion beam, a neutron beam, an alpha-ray, a beta-ray, an X-ray, a γ-ray, or the like, which is emitted from a TEM, a SEM, or the like. The second nanopore 27 of the electrode layer 40 may be simultaneously formed with the first nanopore 25 of the first layer 20. Thus, according to one embodiment, the second nanopore 27 of the electrode layer 40 may be correspondingly coupled or connected to, or otherwise in communication with the first nanopore 25 of the first layer 20 so as to form a single nanopore that extends through the first layer and the electrode layer. The electrode layer 40 may include an electrode contact 41 that is formed through a predetermined portion of the second layer 30 disposed on the electrode layer 40. A voltage may be applied to the nanosensor 200 from an external source through the electrode contact 41. In addition, the electrode contact 41 may be formed of a conductive material. The conductive material may include, for example, Cu, Al, Au, Ag, and the like.

Like the nanosensor 100 of FIG. 1C, the nanosensor 200 may further comprise a housing 11 surrounding the substrate and any associated layers, and the first and second electrodes 15 and 13 that are respectively included in the first region 17 and the second region 18 that are divided with respect to the substrate 10. In addition, the housing 11 may be filled (partially or completely) with a buffer solution such as water, deionized water, an electrolyte solution, or the like. The buffer solution may be a translocation medium of target molecules to be detected by the nanosensor 200. When a voltage is applied to the first and second electrodes 15 and 13 from an external source, a voltage is also applied to the electrode layer 40 so as to control a translocation speed of target molecules approaching the first and second nanopores 25 and 27 through the hole 16 of the substrate 10. For example, if the target molecule is a DNA strand that is negatively charged, when a positive voltage is applied to the electrode layer 40, the DNA strand may rapidly approach the first and second nanopores 25 and 27 due to an electrical attractive force. On the other hand, when a negative voltage is applied to the electrode layer 40, the DNA strand may slowly approach the first and second nanopores 25 and 27 due to an electrical repulsive force.

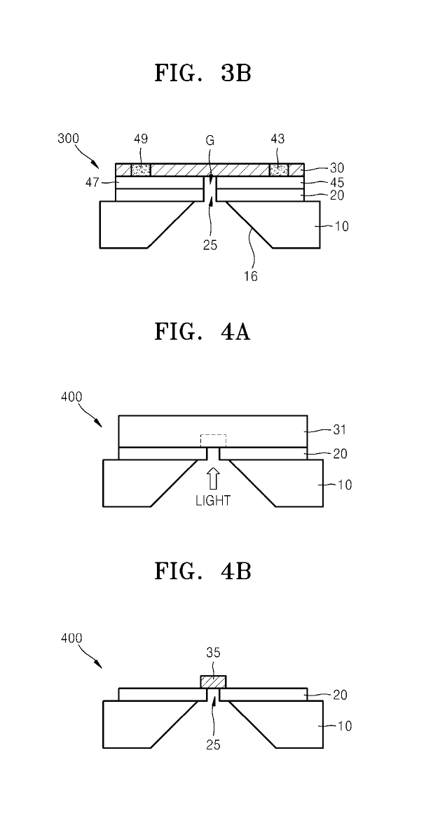

FIG. 3A is a plan view of a nanosensor 300 according to an embodiment of the present invention. FIG. 3B is a cross-sectional view taken along line C-C′ of the nanosensor 300 of FIG. 3A. The nanosensor 300 will be described in terms of its differences from the nanosensors 100 and 200 according to the above-described embodiments of the present invention.

Referring to FIGS. 3A and 3B, the nanosensor 300 comprises a substrate 10 in which an opening defining a hole 16 is formed, the first layer 20 disposed on the substrate 10 and including a first nanopore 25 correspondingly coupled or connected (or otherwise in communication with) to the hole 16, and first and second electrodes 45 and 47 that are spaced apart from each other on the first layer 20 by a nanogap G, wherein the first nanopore 25 is disposed between the first and second electrodes 45 and 47, and the second layer 30 formed of a porous material is disposed on the first layer 20 and the first and second electrodes 45 and 47.

The first and second electrodes 45 and 47 may be formed of a conductive material. The conductive material can comprise, for example, Cu, Al, Au, Ag, and the like. Alternatively, or in addition, the first and/or second electrodes 45 and 47 can comprise at least one graphene sheet. The first and second electrodes 45 and 47 may be disposed on the first layer 20 and may be spaced apart from each other with respect to the first nanopore 25. In addition, the nanogap G may be formed between the first and second electrodes 45 and 47. The size of the nanogap G may be greater than or equal to the diameter of the first nanopore 25 of the first layer 20. FIG. 3B shows a case where the size of the nanogap G is equal to the diameter of the first nanopore 25. First and second electrode contacts 43 and 49 may be present on the first and second electrodes 45 and 47, respectively. The first and second electrode contacts 43 and 49 may each be formed through (e.g., positioned so as to extend through) a predetermined portion of the second layer 30, such that the contacts are exposed through the second layer (e.g., exposed to the outside so as to be accessible for connection to a power source, etc.). A voltage may be applied to the first and second electrode contacts 43 and 49 from an external power source. An electric signal change between the first and second electrodes 45 and 47, that is, between two ends of the nanogap G, may be measured. The first and second electrode contacts 43 and 49 may be formed of a conductive material, for example, Cu, Al, Au, Ag, or the like.

Like the nanosensor 100 of FIG. 1C, the nanosensor 300 may further comprise a housing 11 surrounding the substrate and any associated layers, as well as the third and fourth electrodes 15 and 13 that are respectively included in the first region 17 and the second region 18 that are divided with respect to the substrate 10. In addition, the housing 11 may be filled (partially or completely) with a buffer solution such as water, deionized water, an electrolyte solution, or the like. The buffer solution may be a translocation medium of target molecules to be detected by the nanosensor 300. When a voltage is applied to the third and fourth electrodes 15 and 13 from an external source, since the single-strand DNA 19 is negatively charged, the single-strand DNA 19 may be translocated from the first region 17 including the first electrode 15, that is, a negative electrode, to the second region 18 including the second electrode, that is, a positive electrode, by an electric field generated by the voltage applied to the third and fourth electrodes 15 and 13. That is, the single-strand DNA 19 introduced to the first region 17 is translocated to a region adjacent to the hole 16 of the substrate 10 by the electric field and is guided by the hole 16 towards the first nanopore 25. When the single-strand DNA 19 passes through the nanogap G formed between the first nanopore 25 and the first and second electrodes 45 and 47, the single-strand DNA 19 may reach the second layer 30 that is porous so that a translocation speed of the single-strand DNA 19 is lowered. Thus, when the single-strand DNA 19 passes through the nanogap G, a base constituting the single-strand DNA 19 may be identified by measuring an electric signal change, for example, a tunneling current change between the first and second electrodes 45 and 47. That is, the base constituting the single-strand DNA 19 may be identified by measuring a tunneling current change of the nanogap G at a point of time when the single-strand DNA 19 is passing through the nanogap G. The nanosensor 300 may measure a tunneling current of the nanogap G, instead of measuring the current change of the first nanopore 25.

A method of manufacturing a nanosensor also is provided by the invention. The method comprises (a) forming an opening defining a hole in a substrate; (b) forming a first layer on the substrate; (c) forming a nanopore in the first layer, wherein the nanopore is coupled with, connected to, or otherwise in communication with the opening defining the hole in the substrate; and (d) forming a second layer of a porous material in contact with or coupled to the first layer.

The hole can be formed in the substrate by any suitable method, such as by using a laser drill or by an etching method or the like. When the hole is to have a tapered shape, as previously described, a selective etching method is particularly suitable. The material used for the substrate, and the characteristics of the hole in the substrate, are as previously described with respect to the nanosensor.

The first layer can be deposited on the substrate in any manner suitable for forming a thin film, such as by a coating or depositing method. Methods of coating or depositing thin films of insulator materials, or other suitable materials for the first layer as described herein, on the surface of a substrate, particularly semiconductor substrates, are known in the art.

The nanopore in the first layer can be formed by any suitable technique, such as by using a TEM, a SEM, or the like, or an electron beam, a focused ion beam, a neutron beam, an alpha-ray, a beta-ray, an X-ray, a γ-ray, or the like, which is emitted from a TEM, a SEM, or the like. The material used for the first layer, and the characteristics of the nanopore, are as previously described with respect to the nanosensor.

The method may further comprise forming an electrode layer on the first layer. The electrode layer comprises a conductive material, as previously described, and can be formed by any suitable technique for coating, depositing, or otherwise positioning a conductive material upon the material of the first layer. The electrode layer can be patterned to provide a desired configuration of electrodes. For instance, a second nanopore can be formed in the electrode layer that is in communication with, coupled to, or connected to the first nanopore of the first layer. Or at least a first and second electrodes can be provided, which are separated by a distance establishing a nanogap aligned with the first nanopore so as to be in communication therewith, coupled thereto, or connected therewith. Furthermore, the method can comprise forming the nanopore in the first layer simultaneously with forming the second nanopore or the nanogap in the electrode layer. This can be accomplished, for instance, by forming the first layer on the substrate and forming the electrode layer on the first layer prior to forming the nanopore in the first layer, and subsequently forming a nanopore that extends through both the electrode layer and the first layer. The electrode layer may be patterned before or after forming the nanopore. If the electrode layer is pattered so as to form a first and second electrodes, the pattern can be arranged such that the nanopore in the electrode layer provides a nanogap in the patterned electrode layer.

The second layer may be formed by coating or depositing a porous material, as previously described, on the first layer and, optionally, any electrode layer that may be present. Alternatively, or in addition, the porous material may be coated or deposited within the first nanopore and/or the nanogap, if present. Any suitable technique for coating or depositing the porous material to the desired thickness can be used, for example, spin coating or photolithography techniques. The thickness used will depend, in part, on the particular porous material used and the target molecule to be detected. The thickness should be sufficient to impede passage of the target molecule, thereby reducing the translocation speed of the molecule through the nanosensor (e.g., through the nanopore of the nanosensor), but not so thick as to prevent passage of the molecule.

According to one aspect of the invention, forming the second layer can comprise forming a preliminary second layer by coating or depositing a photosensitive material on the first layer and, optionally, the electrode layer if present, or such portion thereof sufficient to cover and/or at least partially fill the nanopore in the first layer. According to this aspect, the method further comprises curing the preliminary second layer, or at least a portion (i.e., region) thereof (e.g., the portion or region thereof covering and/or at least partially filling the nanopore in the first layer) by irradiating a light on the preliminary second layer or portion thereof. Any light suitable for curing the photosensitive porous material can be used, such as one or more of visible light, ultraviolet (UV) light rays, extreme UV light rays, and X-rays. Optionally, the light can be irradiated on the preliminary second layer or portion thereof by irradiating light from a position below the substrate onto a portion of the substrate below the first layer (i.e., directing the light towards the bottom surface of the substrate). The irradiated light is incident to the bottom surface of the substrate at an angle such that at least a portion of the light is transmitted through the hole in the substrate and the first nanopore in the first layer, optionally as an evanescent wave, to reach the preliminary second layer or potion thereof. Desireably, the first layer is partly or completely opaque to the light used, such that the first layer does not transmit sufficient light to cure the photosensitive porous material, and curing of the preliminary second layer occurs to greater extent or only in the region of the preliminary second layer covering or filling the nanopore. Curing of the preliminary second layer or portion thereof is followed by etching or otherwise removing any remaining uncured portions of the preliminary second layer to provide the second porous layer.

Hereinafter, a method of manufacturing a nanosensor, according to embodiments of the present invention, will be described in detail by reference to the drawings. The description of the embodiments, and references to the drawings, are made for the purpose of further explaining and illustrating the invention, but are not intended to limit the scope of the invention.

Referring to FIGS. 1A and 1B, the method may include forming the hole 16 in the substrate 10, forming the first layer 20 on the substrate 10, forming the first nanopore 25 in the first layer in communication with or connected to the hole 16 in the substrate 20, and forming the second layer 30, formed of a porous material, on the first layer 20.

The substrate 10 may be formed of a semiconductor material, a polymer material, or the like. The semiconductor material may include, for example, silicon (Si), germanium (Ge), GaAs, GaN, or the like. The polymer material may include, for example, an organic polymer or an inorganic polymer. The substrate 10 also may be formed of quartz, glass, or the like. The hole 16 may be formed by using a laser drill or by an etching method or the like. The size of the hole 16 may be several μm or less. The hole 16 may taper from a bottom surface of the substrate 10 toward a top surface of the substrate 10 on which the first layer 20 is disposed. That is, the hole 16 may have a tapered shape that narrows from a lower portion toward an upper portion of the substrate 10 and the tapered shape may be obtained by using a selective etching method.

The first layer 20 may be formed on the substrate 10 by a coating or depositing method. The first layer 20 may be formed of an insulating material. The insulating material can comprise, for example, SiN, SiO₂, Al₂O₃, TiO₂, BaTiO₃, PbTiO₃, or the like. The first nanopore 25 is formed in the first layer 20 so as to be in communication with or connected to the hole 16 of the substrate 10. The first nanopore 25 may be formed by using a TEM, a SEM, or the like. In addition, the first nanopore 25 may be formed by using, for example, an electron beam, a focused ion beam, a neutron beam, an alpha-ray, a beta-ray, an X-ray, a γ-ray, or the like, which is emitted from a TEM, a SEM, or the like. The size of the first nanopore 25 may be selected according to sizes of target molecules to be detected. The diameter of the first nanopore 25 may range from several nm to several tens of nm. For example, the diameter of the first nanopore 25 may range from about 1 nm to about 50 nm.

The second layer 30 may be disposed on the first layer 20 and may be formed of a porous material. The porous material can comprise, for example, gelatin or the like. The thickness and porosity of the second layer 30 may be selected according to a degree of lowering a translocation speed of target molecules to be detected. For example, the thickness of the second layer 30 may range from several nm to several μm. However, if the thickness of the second layer 30 is too great, a friction force at the second layer 30 that is porous is increased compared to a translocation force of target molecules due to an electric field applied from an external source, and thus, the target molecules may not be translocated any more. Thus, in the method according to the present embodiment, the second layer 30 may be formed as a thin layer having a small thickness by using a spin coating method. Alternatively, as shown in FIG. 4A, the second layer 30 may be formed as a thin layer having a small thickness by using a photolithography method. Thus, the second layer 30 that has a sufficiently small thickness and is porous may be formed so as not to prevent a DNA polymer passing through the first nanopore 25 from being translocated. Thus, a nanosensor according to the present embodiment may lower a translocation speed of a DNA polymer, but will not prevent the DNA polymer from being translocated.

Referring to FIG. 4A, in the method of manufacturing the nanosensor, according to the present embodiment, the first layer 20 is formed on the substrate 10. In addition, a preliminary second layer 31 is formed on the first layer 20 by coating or depositing a photosensitive porous material thereupon, such that the photosensive porous material covers the passageway defined by the hole 16 and the first nanopore 25 formed in the substrate 10 and the first layer 20, respectively. Then, the second preliminary layer 31 may be cured by irradiating light from a position below the substrate 10. In other words, light can be directed towards the bottom surface of the substrate, whereby the light is transmitted through the hole and the nanopore to contact and cure at least a portion of the photosensitive porous material. The second layer 35 may be formed by etching the remaining portion of the porous material, which is not cured. In this case, the first layer 20 may be formed of a material that does not transmit the light used to cure the photosensitive porous material, and is partially or completely opaque to such light as compared to the second preliminary layer 31. The first layer 20 may be partially or completely opaque to the light used for curing (e.g., does not transmit light therethrough) and/or may reflect or absorb light. For example, the first layer 20 may be formed of SiN doped with metal, SiₓN_{y}(x>>y) with a very high composition ratio of Si to N, or the like. Alternatively, or in addition, the first layer 20 may comprise at least one metal material that absorbs light and selected from Au, Ag, Al, Cu, and TiN, and may be a thin film with a thickness of several nm or more. When the wavelength of the light used to cure the photosensitive porous material is greater than the diameter of the first nanopore 25, the light might be partially transmitted as an evanescent wave through the first nanopore 25. The evanescent wave may cure the preliminary second layer or portion thereof 31 that is photosensitive and porous. In this case, since the evanescent wave may reach only a portion of the second preliminary layer 31 through the first nanopore 25, the second layer 35 may be formed on a predetermined portion of the first layer 20 so as to cover the first nanopore 25. That is, as shown in FIG. 4B, the second layer 35 may be formed over the first nanopore 25 and on a predetermined portion of the first layer 20 surrounding the first nanopore 25 so as to cover the first nanopore 25.

Referring to FIG. 1C, the method of manufacturing the nanosensor, according to the present embodiment may include forming or otherwise providing a housing 11 surrounding the substrate of the nanosensor 100. The housing 11 may be divided into the first region 17 below the substrate 10 and the second region 18 above the substrate 10. The first and second electrodes 15 and 13 may be formed or otherwise provided in the first and second regions 17 and 18, respectively. The housing 11 may be partially or completely filled with a buffer solution such as water, deionized water, an electrolyte solution, or the like.

Referring to FIGS. 2A and 2B, the method of manufacturing the nanosensor may further comprise forming an electrode layer 40 on the first layer 20, and forming a second nanopore 27 in communication with or connected to the first nanopore 25 of the first layer 20. Referring to FIGS. 3A and 3B, the method may further include forming the electrode layer by providing or forming first and second electrodes 45 and 47 separated by a distance, the distance defining a nanogap G of a dimension that is approximately equal to or greater than the diameter of the nanopore in the fist layer.

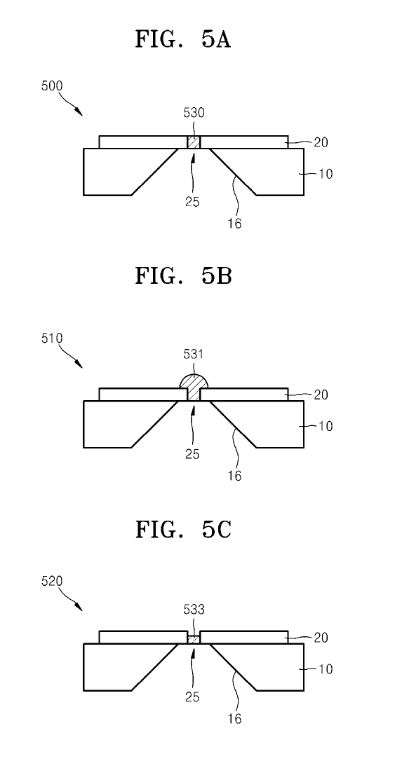

FIGS. 5A through 5C are cross-sectional views of nanosensors 500, 510, and 520 according to embodiments of the present invention.

Referring to FIG. 5A, the nanosensor 500 may include a substrate 10 in which the hole 16 is formed, a first layer 20 disposed on the substrate 10 and including a first nanopore 25 in communication with or connected to the hole 16, and a second layer 530 disposed in the nanopore of the first layer 20 and formed of a porous material.

The first layer 20 optionally does not transmit light (partially or completely opaque to light) or may reflect or absorb light. For example, the first layer 20 may be formed of SiN doped with metal, SiₓN_{y}(x>>y) with a very high composition ratio of Si to N, or the like. Alternatively, or in addition, the first layer 20 can comprise at least one metal material that absorbs light and selected from Au, Ag, Al, Cu, and TiN, and may be a thin film with a thickness of several nm or more.

The second layer 530 may be formed in the first nanopore 25 of the first layer 20. That is, the second layer 530 may partially or completely fill the first nanopore 25. In this embodiment, the second layer is positioned within the nanopore. The second layer 530 may comprise, for example, gelatin, PEGDMA, or the like. The porosity of the second layer 530 may be selected according to a desired degree of lowering a translocation speed of target molecules to be detected. The second layer 530 optionally may be formed by irradiating light from a position below and incident to the bottom surface of the substrate 10, that is, towards the hole 16, and curing a porous material in the first nanopore and/or coated on the first layer 20. For example, the porous material may be cured by ultraviolet (UV) rays that are irradiated from a position below the substrate 10. The porous material may be cured by visible light, extreme UV rays, X-rays, or the like, in addition to UV rays.

Referring to FIG. 5B, the nanosensor 510 may comprise a substrate 10 in which the hole 16 is formed, a first layer 20 disposed on the substrate 10 and including a first nanopore 25 in communication with or connected to the hole 16, and a second layer 531 formed of a porous material. The second layer 531 may be formed with a portion in the first nanopore 25 of the first layer 20 and a portion on the first layer 20 surrounding the first nanopore 25. That is, the second layer 531 may be formed to fill the first nanopore 25 and cover a portion of the first layer 20.

Referring to FIG. 5C, the nanosensor 520 may comprise a substrate 10 in which a hole 16 is formed, a first layer 20 disposed on the substrate 10 and including a first nanopore 25 in communication with or connected to the hole 16, and a second layer 533 formed of a porous material. The second layer 533 may be formed in at least a portion of the first nanopore 25 of the first layer 20. That is, the second layer 533 may be formed to fill a portion of the first nanopore 25, without completely filling the volume of the nanopore. This can be accomplished, for example, if the porous material is cured by irradiating light for a short period of time or irradiating light with a low intensity, such that the preliminary second layer of a photosensitive porous material is not cured though the entire thickness of the layer. The resulting cured second layer 533 may thereby be formed to have a small thickness that is less than the depth of the nanopore through the first layer (i.e., a thickness less than the thickness of the first layer) so that the first nanopore 25 is only partially filled by the porous material after any uncured porous material is removed.

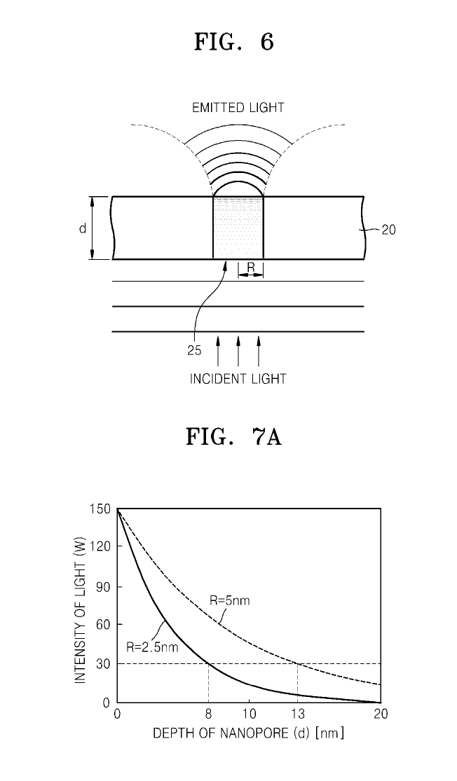

FIG. 6 is a schematic diagram of light incident on the first nanopore 25 and light emitted from the first nanopore 25, according to an embodiment of the present invention.

Referring to FIG. 6, light may be irradiated to a portion below the first layer 20, for example, to the bottom surface of the substrate. Since the first layer 20 may partly or completely prevent light from being transmitted therethrough, incident light may be emitted through the first nanopore 25 but not other portions of the first layer. The first nanopore 25 may diffract light transmitted therethrough, like a single slit. That is, the incident light may proceed in parallel to the direction of the thickness dimension of the first layer 20 (e.g., perpendicular to the bottom surface of the substrate), but the emitted light might not proceed in this direction and may instead be diffracted.

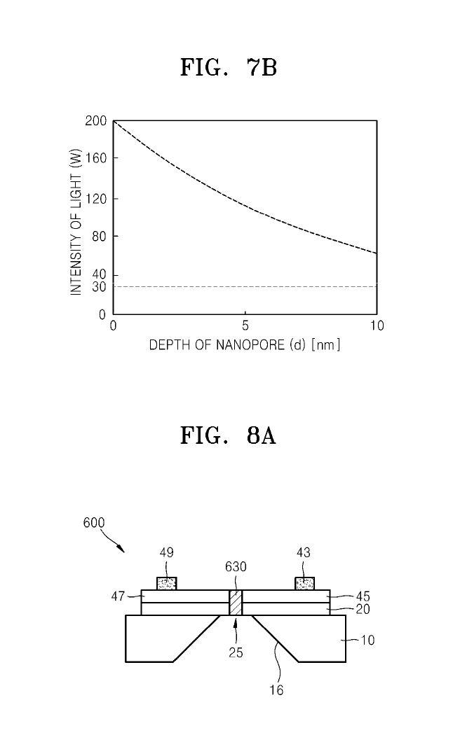

FIGS. 7A and 7B are graphs of an intensity of light according to a depth “d” of a nanopore measured from the substrate towards and through the first layer, according to an embodiment of the present invention.

FIG. 7A shows an intensity of light according to a depth “d” of the first nanopore 25 in the cases where a radius R of the first nanopore 25 is about 5 nm and about 2.5 nm, respectively. The depth “d” of the first nanopore 25 is about 20 nm or more and UV rays with about 150 W are irradiated onto the bottom surface of the substrate 10. As the depth “d” of the first nanopore 25 increases (i.e., the distance measured from the interface of the first layer and the substrate in the direction of the nanopore increases), the intensity of light that reaches the depth of the first nanopore 25 is remarkably reduced. For example, if a critical intensity of light required for curing a porous material is about 30 W, when the radius R of the first nanopore 25 is about 5 nm, the thickness of the second layer 533 (refer to FIG. 5C) may be about 13 nm. When the radius R of the first nanopore 25 is about 2.5 nm, the thickness of the second layer 533 may be about 8 nm. Thus, as the size of a nanopore is reduced, an intensity of light that reaches an inner portion of the nanopore at a given depth is reduced.

FIG. 7B shows an intensity of light according to a depth “d” of the first nanopore 25 when the radius R of the first nanopore 25 is about 5 nm. UV rays with about 200 W are irradiated to the first nanopore 25. For example, if a critical intensity of light required for curing a porous material is about 30 W, the porous material filled in the first nanopore 25 with a radius of about 20 nm or more may be entirely cured. That is, by adjusting an intensity of irradiated light, the thickness of the second layer 533 (refer to FIG. 5C) formed in the first nanopore 25 may be adjusted.

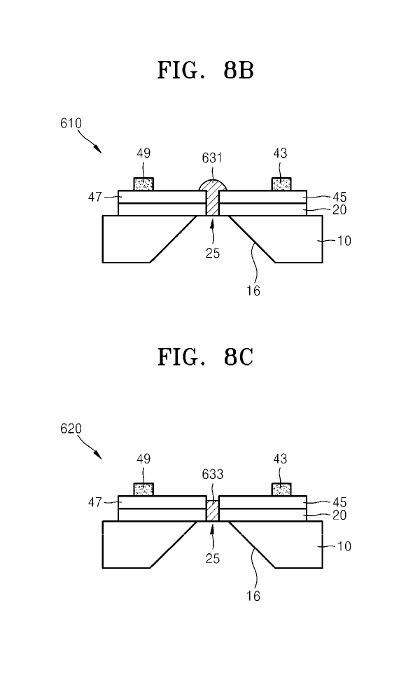

FIGS. 8A through 8C are cross-sectional views of nanosensors 600, 610, and 620 according to other embodiments of the present invention.

Referring to FIG. 8A, the nanosensor 600 may comprise a substrate 10 in which the hole 16 is formed, a first layer 20 disposed on the substrate 10 and including the first nanopore 25 in communication with or connected to the hole 16, first and second electrodes 45 and 47 that are spaced apart from each other on the first layer 20 by a distance forming a nanogap G, wherein the first nanopore 25 is disposed below and between the first and second electrodes 45 and 47 so that the nanopore is in communication with the nanogap, and a second layer 630 disposed in the nanopore first layer 20 and the nanogap G between the first and second electrodes 45 and 47 (e.g., occupying the volume of the nanopore of the first layer and the nanogap) and formed of a porous material.

The first layer 20 may partly or completely prevent the transmission of the light therethrough or may reflect or absorb the light. For example, the first layer 20 may be formed of SiN doped with metal, SiₓN_{y}(x>>y) with a very high composition ratio of Si to N, or the like. In addition, the first layer 20 may be formed of at least one metal material that absorbs light and selected from Au, Ag, Al, Cu, and TiN and may be a thin film with a thickness of several nm or more.

The second layer 630 may be formed in the first nanopore 25 of the first layer 20 and the nanogap G between the first and second electrodes 45 and 47. That is, the second layer 630 may be formed to fill the first nanopore 25 and the nanogap G. The second layer 630 may include, for example, gelatin, PEGDMA, or the like. The porosity of the second layer 630 may be selected according to a degree of lowering a translocation speed of target molecules to be detected. The second layer 630 may be formed by irradiating light to a bottom surface of the substrate 10, that is, to and through the hole 16, and curing a porous material in the nanopore and nanogap, and/or coated on the first layer 20. For example, the porous material may be cured by UV rays irradiated on a bottom surface of the substrate 10. The porous material may be cured by visible light, extreme UV rays, X-rays, or the like, in addition to UV rays. The second layer 630 may be formed only in the first nanopore 25 and nanogap G by removing any uncured photosensitive porous material.

Referring to FIG. 8B, the nanosensor 610 may comprise a substrate 10 in which a hole 16 is formed, a first layer 20 disposed on the substrate 10 and including a first nanopore 25 in communication with or connected to the hole 16, first and second electrodes 45 and 47 that are spaced apart from each other on the first layer 20 by a distance defining a nanogap G, wherein the first nanopore 25 is positioned below and between the first and second electrodes 45 and 47 so that the nanopore is in communication with the nanogap, and a second layer of a porous material 631 disposed in the nanopore of the first layer 20 and the nanogap between the first and second electrodes 45 and 47, and upon at least a portion of the first and second electrodes 45 and 47 to surround the nanogap G. That is, the second layer 631 may be formed to fill the first nanopore 25 and the nanogap G and may cover the nanogap G and a portion of the electrodes.

Referring to FIG. 8C, the nanosensor 620 may comprise a substrate 10 in which the hole 16 is formed, a first layer 20 disposed on the substrate 10 and including a first nanopore 25 in communication with or connected to the hole 16, a first and second electrodes 45 and 47 that are spaced apart from each other on the first layer 20 by a distance defining a nanogap G, and a second layer 633 disposed in the nanopore of the first layer 20 and in at least a portion of the nanogap G between the first and second electrodes 45 and 47, wherein the second layer is formed of a porous material. That is, the second layer 633 can fill the entire first nanopore 25 and at least a portion of the nanogap G. For example, a photosensitive porous material can be deposited onto the first layer and the first and second electrodes so as to cover and fill the first nanopore and the nanogap. If the porous material is cured by irradiating light for a short period of time or irradiating light with a low intensity, the photosensitive material is cured only in the nanopore and part of the nanogap. By removing any uncured material, the second layer 633 may be formed so as to have a thickness less than the combined dimension of the first layer and electrode, so that the nanopore is filled with the porous material and the nanogap G is only partially filled. Alternatively, the second layer 633 may be filled in a portion or all of the first nanopore 25 and not in the nanogap G.

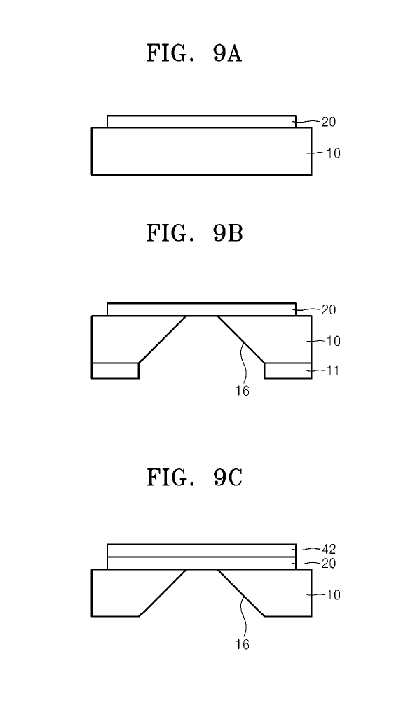

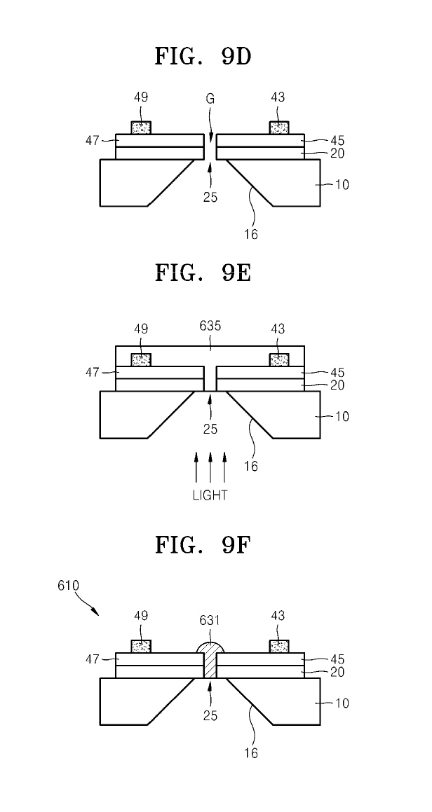

FIGS. 9A through 9F are cross-sectional views for describing a method of manufacturing a nanosensor, according to another embodiment of the present invention.

Referring to FIG. 9A, the first layer 20 can be formed on the substrate 10. The first layer 20 does not transmit light therethrough, i.e., is partly or completely opaque to light, or may reflect or absorb light. For example, the first layer 20 can comprise SiN doped with metal, SiₓN_{y}(x>>y) with a very high composition ratio of Si to N, or the like. Alternatively, or in addition, the first layer 20 can comprise at least one metal material that absorbs light and selected from Au, Ag, Al, Cu, and TiN. The first lay can be a thin film with a thickness of several nm or more.

Referring to FIG. 9B, a mask layer 11 may be formed below the substrate 10 (e.g., on the bottom surface of the substrate) and a hole 16 may be formed by using an etch method. The hole 16 may have a size of several μm or less and may taper from a bottom surface of the substrate 10 toward a top surface of the substrate 10 on which the first layer 20 is disposed. That is, the hole 16 may have a tapered shape that narrows from a lower portion of the substrate 10 to an upper portion of the substrate 10 and the tapered shape may be obtained by using selective etching.

Referring to FIGS. 9C and 9D, a layer 42 of a conductive material may be formed on the first layer 20, and may be patterned to form the first and second electrodes 45 and 47 separated from each other by a distance defining a nanogap G. The first nanopore 25 and the nanogap G may be formed simultaneously or sequentially by using, for example, an electron beam, a focused ion beam, a neutron beam, an alpha-ray, a beta-ray, an X-ray, a γ-ray, or the like. In addition, first and second electrode contacts 43 and 49 may be formed on the first and second electrodes 45 and 47, respectively.

Referring to FIG. 9E, a layer 635 formed of an uncured porous material may be formed by coating an uncured photosensitive porous material on the first layer 20 and the first and second electrodes 45 and 47. The uncured photosensitive porous material may also be filled in the first nanopore 25 and/or the nanogap G. At least a portion of the porous material may be partially cured by irradiating light, for example, UV rays, on a bottom surface of the substrate 10. A degree of curing the porous material may be adjusted according to a wavelength of light irradiated to the porous material, the intensity of the light, the temperature, the time taken to irradiate light (duration of irradiation), the depth “d” of the first nanopore 25, the radius of the first nanopore 25, and the like.

When a wavelength of the light is greater than the diameter of the first nanopore 25, the light may not be wholly transmitted through the first nanopore 25, but the light may be partially transmitted as an evanescent wave. The evanescent wave may cure the layer 635 that is photosensitive and porous. In this case, since the evanescent wave may reach only a portion of the layer 635 through the first nanopore 25, the resulting second layer 631 may be formed on a portion of the first and second electrodes 45 and 47 convering the first nanopore and nanogap G.

Referring to FIG. 9F, the remaining portion of the porous material, which is not cured, may be etched to be removed. Thus, the second layer 631 may be formed in the first nanopore 25 and the nanogap G formed between the first and second electrodes 45 and 47, and may be formed on the first and second electrodes 45 and 47 to surround the nanogap G. That is, the second layer 631 may be filled in the first nanopore 25 and the nanogap G and may cover the nanogap G.

A nanosensor according to the present embodiment may reduce a translocation speed of a DNA polymer passing through the nanopore and can be used to identify bases constituting the DNA polymer. Thus, the nanosensor according to the present embodiment provides a next-generation sequencing method that is rapid and accurate. By using the method of manufacturing the nanosensor, a porous layer having a sufficiently small thickness may be formed so as not to prevent a DNA polymer from passing through the nanosensor, yet allowing for a sufficient reduction in translocation speed to allow for identification of the bases of the DNA.

It should be understood that the exemplary embodiments described herein should be considered in a descriptive sense only and not for purposes of limitation. Descriptions of features or aspects within each embodiment should typically be considered as available for other similar features or aspects in other embodiments.

What is claimed is:

1. A nanosensor comprising:
a substrate comprising an opening defining a hole;
a first layer disposed on the substrate and comprising a first nanopore in communication with the hole in the substrate; and
a second layer coupled to or contacted with the first layer and formed of a porous material.

2. The nanosensor of claim 1, wherein the porous material comprises gelatin or poly(ethylene glycol) dimethacrylate (PEGDMA).

3. The nanosensor of claim 1, wherein the first layer comprises at least one selected from SiN, SiO₂, Al₂O₃, TiO₂, BaTiO₃, and PbTiO₃.

4. The nanosensor of claim 1, wherein the first layer comprises at least one selected from gold (Au), silver (Ag), aluminum (Al), copper (Cu), and TiN.

5. The nanosensor of claim 1, wherein the first layer prevents light from being transmitted therethrough.

6. The nanosensor of claim 1, wherein the second layer is disposed on the first layer.

7. The nanosensor of claim 1, wherein the second layer is disposed on a predetermined portion of the first layer so as to cover the first nanopore.

8. The nanosensor of claim 1, wherein the second layer is filled in at least a portion of the first nanopore.

9. The nanosensor of claim 1, further comprising an electrode layer disposed on the first layer.

10. The nanosensor of claim 9, wherein the electrode layer comprises a first electrode and a second electrode that are spaced apart from each other by a nanogap, wherein the nanogap is in communication with the first nanopore.

11. The nanosensor of claim 1, further comprising a housing surrounding the substrate and divided into a first and second regions with respect to the substrate.

12. The nanosensor of claim 11, wherein the first and second regions each further comprise a third electrode and a fourth electrode, respectively.

13. The nanosensor of claim 11, wherein the housing contains water or an electrolyte solution.

14. A method of manufacturing a nanosensor, the method comprising:
forming an opening defining a hole in a substrate;
forming a first layer on the substrate;
forming a nanopore in communication with the hole in the substrate; and
forming a second layer of a porous material coupled to or contacted with the first layer.

15. The method of claim 14, further comprising forming an electrode layer on the first layer.

16. The method of claim 14, wherein the second layer is formed by coating a porous material on the first layer.

17. The method of claim 14, wherein the nanopore is formed in the first layer by irradiating any one selected from an electron beam, a focused ion beam, a neutron beam, an alpha-ray, a beta-ray, an X-ray, and a γ-ray.

18. The method of claim 14, wherein forming the second layer comprises:
spin-coating a porous material which is photosensitive on the first layer;
curing a portion of the porous material by irradiating light onto a bottom surface of the substrate, wherein the light is transmitted through the hole of the substrate to contact at least a portion of the photosensitive porous material; and
forming the second layer by etching the remaining portion of the porous material, which is not cured.

19. The method of claim 18, wherein curing the porous material comprises transmitting an evanescent light wave through the hole of the substrate.

20. The method of claim 18, wherein the light comprises at least one of visible light, ultraviolet (UV) rays, extreme UV rays, and X-rays.

21. The method of claim 14, wherein the second layer is formed on the first layer.

22. The method of claim 14, wherein the second layer is formed on a predetermined portion of the first layer so as to cover the nanopore.

23. The method of claim 14, wherein the second layer is filled in at least a portion of the nanopore.
